(19) United States
(12) Patent Application Publication
(10) Pub. No.: US 2016/0133758 A1
(43) Pub. Date: May 12, 2016

(54) DUAL STACK VARACTOR

(71) Applicant: TriQuint Semiconductor, Inc.

(72) Inventor: Peter V. Wright, Portland, OR (US)

(21) Appl. No.: 14/995,329

(22) Filed: Jan. 14, 2016

Related U.S. Application Data
(63) Continuation-in-part of application No. 14/273,316, filed on May 8, 2014.
(60) Provisional application No. 62/174,573, filed on Jun. 12, 2015.
(60) Provisional application No. 62/157,782, filed on May 6, 2015.

(51) Int. Cl. H01L 29/93

(52) U.S. Cl. CPC H01L 29/93

(57) ABSTRACT

Embodiments include apparatuses and methods related to vertically stacked varactors. Specifically two varactors may be constructed of vertically stacked layers including an anode layer, a contact layer, and a varactor layer. The two varactors may share one or more layers in common and may be electrically coupled to form a parallel varactor pair. In some embodiments the two varactors may share the anode layer in common, while in other embodiments the two varactors may share the contact layer in common. The parallel varactor pair may be advantageous in reducing die area for compound varactor circuits.

### Related Applications

This application claims the benefit of U.S. provisional patent application No. 62/157,782 filed May 6, 2015 and of U.S. provisional patent application No. 62/174,573 filed Jun. 12, 2015, and is a continuation-in-part of co-pending U.S. patent application Ser. No. 14/273,316, entitled “DUAL STACK VARACTOR,” which was filed on May 8, 2014, the disclosures of which are incorporated herein by reference in their entireties.

### FIELD

Embodiments of the present disclosure relate generally to the field of circuits, and more particularly to varactors.

### BACKGROUND

Varactors may be diodes that act as voltage-controlled capacitors. As a control voltage across a layer of the varactor varies, the capacitance of the varactor may also vary. This variance may be called “tuning.” Generally, semiconductor varactors may have a wider tuning range (i.e. capacitance variance) and lower control voltage requirements than dielectric varactors realized on materials such as barium strontium titanate (BST). However, the semiconductor varactors may typically achieve a lower capacitance per unit area than a dielectric varactor, thereby requiring a larger die area to implement a given capacitance.

Generally, a varactor may be considered a two-port device, i.e. having two input terminals and two output terminals. As such, varactors may be prone to self-modulation distortion resulting from applied radio frequency (RF) voltages. This self-modulation distortion may introduce nonlinearity into a circuit using the varactors. To reduce this nonlinearity to acceptable levels, a number of individual varactors may be coupled in series to divide the RF voltage across them. If the number of varactors in the series is n, then the die area on the circuit board required to realize a desired net capacitance may be increased by a factor of n² if the varactors are co-planar to one another. If a relatively large number of varactors is used, then this circuit may make the required die area prohibitively large for use in modern devices.

### SUMMARY

The present disclosure relates to varactors, and in particular to varactor diodes. In certain embodiments, a semiconductor includes one or more epitaxial stacks positioned over a substrate. A first epitaxial stack may include an upper varactor vertically disposed over a lower varactor. By vertically disposing the upper varactor over the lower varactor, a die area occupied by the pair of varactors may be significantly reduced.

In one embodiment, a lower contact layer may be positioned over the substrate. A lower varactor layer having a first doping profile may be positioned over the lower contact layer. The first doping profile may be an abrupt, hyper-abrupt, or linear n− doping profile. Further, a common contact layer may be positioned over the lower varactor layer. The lower contact layer, the lower varactor layer, and the common contact layer may form a lower varactor.

An upper varactor layer may be positioned over the common contact layer. The upper varactor layer may have a second doping profile that is inverted with respect to the first doping profile. Further, an upper contact layer may be positioned over the upper varactor layer. The common contact layer, the upper varactor layer, and the upper contact layer may form an upper varactor.

A first intra-connect structure may electrically couple the lower contact layer and the upper contact layer such that the lower varactor and the upper varactor are placed in parallel to form a first multi-varactor module. The first intra-connect structure may be a surface metallization structure or a wire bond structure. Further, the first intra-connect structure may electrically couple to an upper ohmic contact positioned on the upper contact layer and electrically couple to a lower ohmic contact positioned on the lower contact layer. An ohmic contact may also be positioned on the common contact layer.

The common contact layer may include an upper common contact layer directly coupled with the upper varactor layer and a lower common contact layer directly coupled with the lower varactor layer. A common etch stop layer may be positioned between and directly coupled with the upper common contact layer and the lower common contact layer. Further, the lower contact layer may include a top lower contact layer directly coupled with the lower varactor layer and a bottom lower contact layer directly coupled with the substrate. A lower etch stop layer may be directly coupled with and positioned between the top lower contact layer and the bottom lower contact layer.

In some embodiments, the common contact layer may be a common anode layer for the upper and lower varactors. The upper and lower contact layers may be cathode layers for each of the varactors. The common anode layer may be P+ doped and the cathode layers may be N+ doped.

In other embodiments, the common contact layer may be a common cathode layer for the upper and lower varactors. The upper and lower contact layers may be anode layers for each of the varactors. The common cathode layer may be N+ doped and the anode layers may be P+ doped.

In further embodiments, a second multi-varactor module may be formed over the substrate and adjacent to the first multi-varactor module. The second multi-varactor module may be formed essentially the same as the first multi-varactor module and may be electrically coupled with the first multi-varactor module.

In other embodiments, one or more resistors may be electrically coupled with an intra-connect structure of one or more of multi-varactor modules. The resistors and multi-varactor modules may form a compound varactor circuit.

A process may include first deposing a plurality of P-type and N-type layers on the substrate, and then etching to form a plurality of epitaxial stacks, wherein adjacent layers in each epitaxial stack have essentially the same composition.

### BRIEF DESCRIPTION OF THE DRAWINGS

Embodiments are illustrated by way of example and not by way of limitation in the figures of the accompanying drawings, in which like references indicate similar elements and in which:

FIG. 1 illustrates an example compound varactor circuit, in accordance with various embodiments.

FIG. 2 illustrates a general example of a dual varactor stack, in accordance with various embodiments.

FIG. 3 illustrates an alternative general example of a dual varactor stack, in accordance with various embodiments.

FIG. 4 illustrates a specific example of a dual varactor stack, in accordance with various embodiments.

FIG. 5 illustrates an alternative specific example of a dual varactor stack, in accordance with various embodiments.

FIG. 6 illustrates a process for constructing a dual varactor stack, in accordance with various embodiments.

FIG. 7 is a block diagram of an exemplary wireless communication device, in accordance with various embodiments.

FIG. 8a illustrates a simplified example of a parallel varactor pair in a multi-varactor module that includes a dual varactor stack configured in a back to back configuration, in accordance with various embodiments.

FIG. 8b illustrates a plurality of epitaxial layers and an intra-connect structure of FIG. 8a, in accordance with various embodiments.

FIG. 8c illustrates a schematic overlay on the epitaxial layers of FIG. 8b further illustrating the parallel varactor pair, in accordance with various embodiments.

FIG. 8d illustrates a schematic representation of the parallel varactor pair, in accordance with various embodiments.

FIG. 8e illustrates a single varactor schematic representation of FIG. 8d, in accordance with various embodiments.

FIG. 9a illustrates a plurality of epitaxial stacks of a multi-varactor assembly having two multi-varactor modules of FIG. 8c, in accordance with various embodiments.

FIG. 9b illustrates a schematic representation of FIG. 9a, in accordance with various embodiments.

FIG. 9c illustrates a simplified schematic representation of FIG. 9b, in accordance with various embodiments.

FIG. 10a illustrates a schematic representation of a multi-varactor assembly having four multi-varactor modules of FIG. 8d, in accordance with various embodiments.

FIG. 10b illustrates a simplified schematic representation of FIG. 10a, in accordance with various embodiments.

FIG. 11a illustrates a schematic representation of an alternate multi-varactor assembly having four multi-varactor modules of FIG. 8d, in accordance with various embodiments.

FIG. 11b illustrates a simplified schematic representation of FIG. 11a, in accordance with various embodiments.

FIG. 12 illustrates a simplified example of a parallel varactor pair in a multi-varactor module that includes a dual varactor stack configured in a front to front configuration, in accordance with various embodiments.

FIG. 13a illustrates a schematic representation of a multi-varactor assembly having four multi-varactor modules of FIG. 12, in accordance with various embodiments.

FIG. 13b illustrates a simplified schematic representation of FIG. 13a, in accordance with various embodiments.

FIG. 14a illustrates a schematic representation of an alternate multi-varactor assembly having four multi-varactor modules of FIG. 12, in accordance with various embodiments.

FIG. 14b illustrates a simplified schematic representation of FIG. 14a, in accordance with various embodiments.

FIG. 15 illustrates a simplified example of a dual varactor stack configured in a front to back configuration, in accordance with various embodiments.

FIG. 16a illustrates a schematic representation of a multi-varactor assembly having four dual varactor stacks of FIG. 15, in accordance with various embodiments.

FIG. 16b illustrates a simplified schematic representation of FIG. 16a, in accordance with various embodiments.

FIG. 17 illustrates a simplified example of an alternate dual varactor stack configured in a front to back configuration, in accordance with various embodiments.

FIG. 18a illustrates a schematic representation of a multi-varactor assembly having four dual varactor stacks of FIG. 17, in accordance with various embodiments.

FIG. 18b illustrates a simplified schematic representation of FIG. 18a, in accordance with various embodiments.

FIG. 19 illustrates a simplified example of a dual varactor stack configured in a back to front configuration, in accordance with various embodiments.

FIG. 20a illustrates a schematic representation of a multi-varactor assembly having four dual varactor stacks of FIG. 19, in accordance with various embodiments.

FIG. 20b illustrates a simplified schematic representation of FIG. 20a, in accordance with various embodiments.

FIG. 21 illustrates a simplified example of an alternate dual varactor stack configured in a back to front configuration, in accordance with various embodiments.

FIG. 22a illustrates a schematic representation of a multi-varactor assembly having four dual varactor stacks of FIG. 21, in accordance with various embodiments.

FIG. 22b illustrates a simplified schematic representation of FIG. 22a, in accordance with various embodiments.

FIG. 23 illustrates an alternate example of a single stack compound varactor circuit, in accordance with various embodiments.

FIG. 24 illustrates an example of a compound varactor circuit having dual asymmetric varactor stacks, in accordance with various embodiments.

FIG. 25 illustrates an alternate example of a compound varactor circuit having a single series of reversed biased varactors, in accordance with various embodiments.

### DETAILED DESCRIPTION

Embodiments include apparatuses and methods related to vertically stacked varactors. Specifically two varactors may be constructed of vertically stacked layers including an anode layer, a contact layer, and a varactor layer. The two varactors may share one or more layers in common. In some embodiments the two varactors may share the anode layer in common, while in other embodiments the two varactors may share the contact layer in common.

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific devices and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the present disclosure; however, the order of description should not be construed as to imply that these operations are necessarily order dependent. In particular, these operations need not be performed in the order of presentation.

The phrase “in one embodiment” is used repeatedly. The phrase generally does not refer to the same embodiment; however, it may. The terms “comprising,” “having,” and “including” are synonymous, unless the context dictates otherwise.

In providing some clarifying context to language that may be used in connection with various embodiments, the phrases “NB” and “A and/or B” mean (A), (B), or (A and B); and the phrase “A, B, and/or C” means (A), (B), (C), (A and B), (A and C), (B and C) or (A, B and C).

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

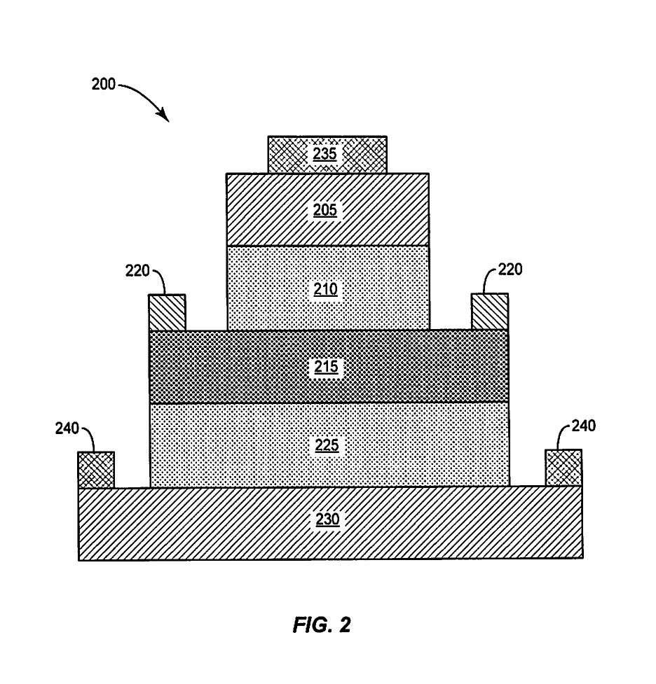

FIGS. 2-5 may depict various vertical stacks of layers which may be epitaxially deposited. The sizes, widths, or heights of the various layers are not drawn to scale, and should not be assumed to be limited to being identical to, or different from, one another unless explicitly indicated to be so in the current specification.

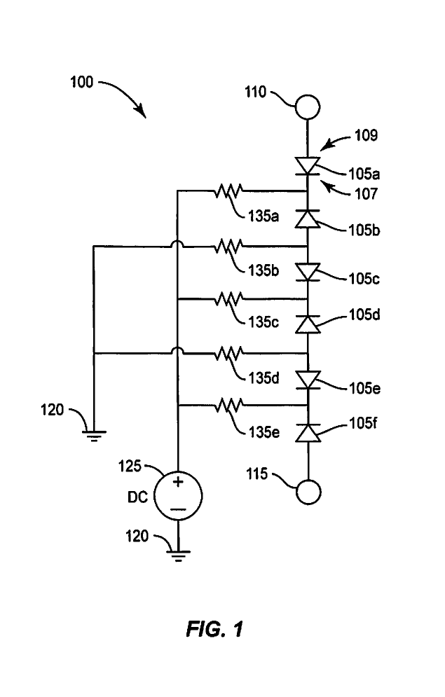

FIG. 1 illustrates an example circuit diagram of a compound varactor 100, in accordance with various embodiments. The compound varactor 100 may include a plurality of varactors such as varactors 105a, 105b, 105c, 105d, 105e, or 105f (collectively varactors 105) generally positioned between an input terminal 110 and an output terminal 115. In some embodiments, the input terminal 110 may be configured to receive a radio frequency (RF) signal which then propagates through the compound varactor 100 to the output terminal 115. In some embodiments, one or more of the varactors 105 may be connected in parallel with the input terminal 110 and the output terminal 115, in which case the RF signal may not propagate through the compound varactor 100 to the output terminal 115.

In some embodiments, each of the varactors 105 may have a “front” side and a “back” side. FIG. 1 depicts the front side 107 and back side 109 of varactor 105a. In some embodiments, the front side 107 of varactor 105a may be referred to as the “cathode” of varactor 105a, and the back side 109 of varactor 105a may be referred to as the “anode” of varactor 105a. In FIG. 1, each of the varactors 105 may have a front side and a back side (or cathode and anode), though specific designators in FIG. 1 are omitted for each varactor for the sake of clarity.

In some embodiments, two or more of the varactors 105 may be coupled to one another in a back-to-back configuration. Specifically, the anodes of the varactors may be coupled directly to one another. For example, varactors 105b and 105c may be considered to be in a back-to-back configuration as shown in FIG. 1. In other embodiments, the varactors 105 may be coupled to one another in a front-to-front configuration as shown in FIG. 1. Specifically, the cathodes of the varactors may be coupled directly to one another. For example, varactors 105a and 105b may be considered to be in a front-to-front configuration as shown in FIG. 1.

In some embodiments, the front sides of one or more of the varactors 105 may be coupled to ground 120. Additionally, the back sides of one or more of the varactors 105 may be coupled to a DC power source 125. The DC power source 125 may be configured to provide a control voltage (V_{CTRL}) to reverse bias the varactors 105, as will be explained in further detail below. In some embodiments, V_{CTRL} may be between approximately 2 Volts (V) and approximately 18 V, while in other embodiments V_{CTRL} may be between approximately −1.2 V and approximately 3 V.

In embodiments one or more resistors such as resistors 135a, 135b, 135c, 135d, and 135e (collectively resistors 135) may be positioned between the varactors 105 and the ground 120 or the DC power source 125. In some embodiments, the outer resistors such as resistors 135a and/or 135e may have a resistance up to twice the resistance of resistors 135b, 135c, or 135d. The increased resistance may be selected to equalize the charging time constant of all the capacitors in the stack.

In some embodiments, the resistance of resistors 135a and/or 135e may be approximately 60 kΩ, while in other embodiments the resistance of resistors 135a and/or 135e may be between approximately 20 kΩ and approximately 60 kΩ. Similarly, in some embodiments the resistance of resistors 135b, 135c, or 135d may be approximately 30 kΩ, while in other embodiments the resistance of resistors 135b, 135c, or 135d may be between approximately 10 kΩ and approximately 30 kΩ. In other embodiments, a resistor (not shown) may be positioned between the input terminal 110 and ground 120, and a resistor (not shown) may be positioned between the output terminal 115 and ground.

As shown above, the compound varactor 100 may include a number of varactors 105 and resistors 135, although only six varactors 105 and five resistors 135 are shown in FIG. 1. In other embodiments the compound varactor 100 may include a greater or lesser number of varactors 105 or resistors 135. In some embodiments, it may be desirable for the compound varactor 100 to include at least the resistors 135a and 135e. In some embodiments, inductors may also be used in place of, or in combination with, the resistors 135. As discussed above, as the number of varactors 105 in the compound varactor 100 increases, the area that the compound varactor 100 requires on a die may increase exponentially if all of the varactors 105 are co-planar to one another. In some embodiments, the DC power source 125 may be configured to supply a positive V_{CTRL} and be coupled to the front side, or cathode, of each of the varactors 105, while the ground 120 may be coupled to the back side 109, or anode, of each of the varactors 105, as discussed in further detail below. Other more complicated circuits may be envisioned having multiple DC power sources 1 25 that may each supply different or similar positive or negative voltages, or multiple ground connections.

Typically, a legacy compound varactor may be implemented in common epitaxial layers of a gallium arsenide heterojunction bipolar transistor (HBT). Typically, only the lower epitaxial layers, which are commonly used for implementing the collector-base junction of an HBT, may be used for the varactors 105. This may be because the upper level epitaxial layers of the HBT may be optimized by specific doping of the layers for implementing the emitter-base bipolar junction. This doping may render the upper epitaxial layers of the HBT undesirable or unsuitable for implementing a useful varactor.

However, if a different process is used, and the requirement for a bipolar device is removed, then a more advantageous epitaxial structure may be available. Specifically, if the upper layers of an epitaxial structure are not doped to implement an emitter-base bipolar junction, then a useful varactor may be additionally implemented in the upper layers of the epitaxial structure.

FIG. 2 illustrates a general example of a dual varactor stack 200, in accordance with various embodiments. Generally, a varactor, as discussed herein, may be considered to be made up of three layers. Specifically, a varactor may be considered to be made up of a contact layer, a varactor layer, and an anode layer. In some embodiments, the anode layer may additionally be referred to as a “contact” layer of the varactor, but for the sake of description herein the anode layer will be generally referred to as “anode layer,” unless explicitly indicated otherwise. In this embodiment, the contact layer may be considered to be the cathode of the varactor. In some embodiments, a varactor may only be considered to comprise the varactor layer and the anode layer, wherein the varactor layer would be considered to be the cathode; however as discussed herein for the sake of consistency the varactor will be described as having three layers. The three layers of the varactor will be discussed in further detail below.

In embodiments, the stack 200 may include a plurality of epitaxial layers in which two varactors are implemented in a vertical, rather than co-planar, fashion. Specifically, the stack 200 may include a first varactor that is comprised of a contact layer 205, varactor layer 210, and anode layer 215 as described above. The anode layer 215 may be a p+ anode layer. The designator “p+” may indicate that the anode layer 215 is heavily doped with a positively charged impurity such as carbon, zinc, beryllium, or some other appropriate positively charged dopant. For example, the anode layer 215 may be constructed of one or more of a semiconductor material such as gallium arsenide, silicon, germanium, aluminum phosphide, aluminum arsenide, indium phosphide, gallium nitride, combinations or alloys thereof, or some other semiconductor material, with an amount of the positively charged dopant material mixed in. A p+ layer may include on the order of one atom of the positively charged dopant per ten thousand atoms of the semiconductor material. In other embodiments, the p+ anode layer may have higher than approximately 1×10¹⁹ cm-3 doping. In some embodiments, the anode layer 215 may have a vertical or z-height of between approximately 0.05 microns (μm) and approximately 0.5 μm.

Similarly, the contact layer 205 may be referred to as an n+ contact layer. The designator “n+” may indicate that the contact layer 205 is heavily doped with a negatively charged impurity such as silicon or some other appropriate negatively charged dopant. For example, the contact layer 205 may be constructed of a semiconductor material such as the semiconductor material described above with an amount of the negatively charged dopant material mixed in. A n+ layer may include on the order of one atom of the negatively charged dopant per ten thousand atoms of the semiconductor material. In other embodiments, the n+ contact layer may have higher than approximately 1×10¹⁸ cm-3 doping. In some embodiments, the contact layer 205 may have a vertical or z-height of between approximately 0.05 μm and 1.0 μm.

The varactor layer 210 may be referred to as an n− varactor layer. The designator “n−” may indicate that the varactor layer 210 is relatively lightly doped with a negatively charged impurity such as the negatively charged dopants described above. Specifically, an n− layer may include on the order of one atom of the negatively charged dopant per one hundred million atoms of the semiconductor material. In other embodiments, the n− varactor layer may have between approximately 1×10¹⁴ and approximately 1×10¹⁸ cm-3 doping. In some embodiments, the varactor layer 210 may have a vertical or z-height of between approximately 0.2 μm and 3 μm.

The stack 200 may also include one or more p+ ohmic contacts such as ohmic contacts 220. In embodiments, the ohmic contacts 220 may be comprised of titanium (Ti), platinum (Pt), gold (Au), zinc (Zn), nickel (Ni), beryllium (Be), or combinations or alloys thereof such as Ti/Pt/Au, Pt/Au, Ti/Au, Pt/Ti/Pt/Au, AuZn/Ni/Au, AuBe/Ni/Au, or other p-type contacts. The ohmic contacts 220 may be directly coupled to the anode layer 215, and also coupled to a DC power source such as DC power source 125 of FIG. 1. In embodiments, the ohmic contacts 220 may be configured to receive a negative DC voltage that will reverse-bias the varactor. Specifically, the negative DC voltage applied to the anode layer 215 may cause the voltage at the cathode (i.e. the contact layer 205) to be higher than the voltage at the anode layer 215. This higher voltage at the cathode of the varactor may result in no current flowing through the varactor until the varactor breaks down.

The stack 200 may further include a second varactor that may be comprised of anode layer 215, varactor layer 225, and contact layer 230. Varactor layer 225 may be an n− varactor layer that may be similar to varactor layer 210. In some embodiments varactor layer 225 and varactor layer 210 may be comprised of the same material as one another, while in other embodiments the varactor layers 225 and 210 may be comprised of different materials. Similarly, the contact layer 230 may be an n+ contact layer that may be similar to contact layer 205. In some embodiments contact layer 230 and contact layer 205 may be comprised of the same material as one another, while in other embodiments the contact layers may be comprised of different materials.

The stack may further include one or more n+ ohmic contacts such as ohmic contacts 235 or 240. Specifically, the n+ ohmic contacts 235 and 240 may be coupled with the n+ contact layers 205 or 230, as shown in FIG. 2. In some embodiments. The n+ ohmic contacts 235 and 240 may be comprised of one or more of Au, germanium (Ge), Ni, Au, Ti, Pt, tungsten (W), silicon (Si), or combinations or alloys thereof such as AuGe/Ni/Au, Ti/Pt/Au, Pt/Au, Ti/Au, TiW/Ti/Pt/Au, WSi/Ti/Pt/Au, or other ohmic contacts. In some embodiments, the n+ ohmic contacts 235 and 240 may be formed of the same material or different materials from one another. In some embodiments, the ohmic contacts 235 or 240 may be topped with a different metal that is used to make contact with another device, terminal, or chip.

In embodiments, the n+ ohmic contacts 235 and 240 may be considered the input and output terminals of the stack 200. For example, one or the other of the n+ ohmic contacts 235 or 240 may be configured to receive an RF signal, for example from the input terminal 110, another varactor, or some other source. The other of the n+ ohmic contacts 235 or 240 may be configured to output an RF signal, for example to the output terminal 115, another varactor, or some other source.

As can be seen, the first varactor and the second varactor of the stack 200 may share anode layer 215. Specifically, the two varactors of stack 200 may be considered to be in a vertically stacked back-to-back configuration, as described above. As discussed above, the z-height of the anode layer 215 may be relatively small compared to the z-height of the varactor layers 210 or 225, or the z-height of the contact layers 205 or 230. This may be because the sheet resistance of layer 215 may not significantly change the performance of the stack 200.

Because it may be important that the two varactors of the stack 200 have the same or similar tuning characteristics, for example experience similar equal change in capacitance with respect to change in voltage, the epitaxial doping of the top n− varactor layer 210 may be chosen to be identical, but inverted, with respect to the doping of the lower n− varactor layer 225. These two n− varactor layers 210 and 225, which may be symmetric about their shared p+ anode layer 215, may form the depletion layers of the two varactor diodes. The two n− varactor layers 210 and 225 may also serve as the varactor capacitor dielectrics, and may be created with an abrupt, hyper abrupt, or linear doping profile. In other embodiments, one or more other doping profiles suitable to the application may also be employed.

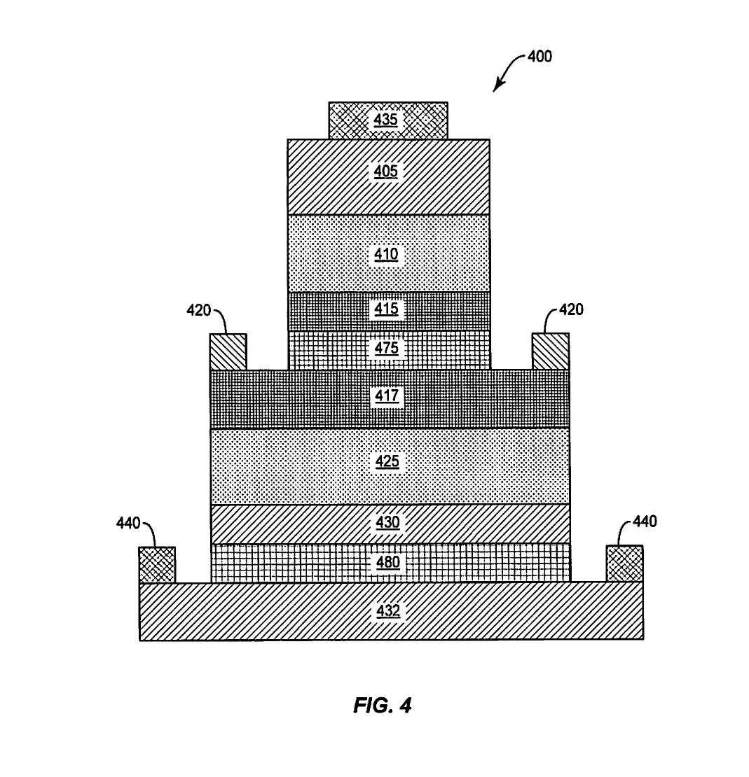

The stack 200 may exhibit several clear advantages over previously existing compound varactors. For example, stack 200 may nearly double the effective capacitance per unit die area that can be achieved compared to previously existing compound varactor architectures. This increase in effective capacitance may result in enabling higher performance at the high degree of stacking that may be required to meet challenging intermodulation performance requirements. A specific implementation of the varactor lattice matched gallium arsenide may be described below with respect to FIGS. 4 and 5. However, in other embodiments one or more layers of the stack 200 may include silicon, indium phosphide, or other suitable materials. In embodiments, etch stop layers may be inserted to facilitate construction of the stack 200, as described in further detail below with respect to FIGS. 4 and 5.

Stack 200 may provide an additional advantage. In conventional diode stacking, such as that discussed with respect to FIG. 1, the RF signal may flow between two varactors in a back-to-back configuration via the bottom n+ contact layer. However, this n+ contact layer may typically have significant resistivity, on the order of 5 or more ohms. This resistivity may contribute to conductive losses in the varactor diode, thereby degrading the quality factor of the varactor. However, in the stack 200, the RF energy may transit directly across the relatively thin shared p+ anode layer of the two varactor diodes, and thus should suffer significantly reduced conductive losses.

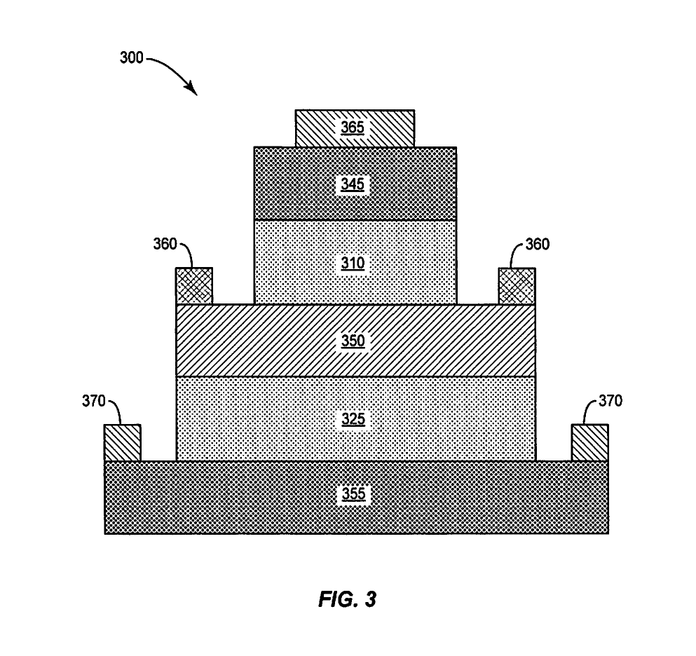

FIG. 3 depicts an alternative embodiment of a varactor stack 300 that may include two varactors in a front-to-front configuration. The first varactor may include an n− varactor layer 310, a p+ anode layer 345, and an n+ contact layer 350. The n− varactor layer 310 may be similar to n− varactor layer 210 of FIG. 2. The p+ anode layer 345 may be similar to p+ anode layer 215. The n+ contact layer 350 may be similar to n+ contact layer 205. However, in the stack 300, in some embodiments the p+ anode layer 345 may have a z-height of between approximately 0.05 μm and approximately 1.0 μm, while the n+ contact layer 350 may have a z-height of between approximately 0.05 μm and approximately 0.5 μm. In specific embodiments, the z-height of the p+ anode layer 345 may be approximately 0.3 μm, while the z-height of the n+ contact layer 350 may be approximately 0.3 μm.

The stack 300 may further include a second varactor that may include the n+ contact layer 350, an n− varactor layer 325, and a p+ anode layer 355. The n− varactor layer 325 may be similar to n− varactor layer 310 discussed above. The p+ anode layer 355 may be similar to p+ anode layer 345 described above. Instead of the two varactors of the stack sharing the anode layer, as discussed above with respect to stack 200 of FIG. 2, the two varactors of stack 300 may share the n+ contact layer, resulting in the face-to-face configuration described above. In some embodiments, the z-height of the n+ contact layer 350 may be less than the z-height of the p+ anode layers 345 or 355. This may be because, as discussed above, the sheet resistance of layer 350 may not significantly change the performance of the stack 300.

The stack 300 may further include n+ ohmic contacts 360, which may be similar to n+ ohmic contacts 235 or 240 discussed above. In the stack 300, ohmic contacts 360 may be coupled with the n+ contact layer 350 and configured to receive power from DC power source 125. In stack 300, the DC power source 125 may supply a positive voltage to the ohmic contacts 360, and through the ohmic contacts 360 to the n+ contact layer 350. This positive voltage may result in the voltage of the n+ contact layer 350 being higher than the voltage of the p+ anode layers 345 and/or 355. As described above, this higher voltage at the n+ contact layer 350 may result in the varactors of the stack 300 being reverse biased.

Finally, the stack 300 may additionally include one or more p+ ohmic contact such as ohmic contacts 365 and 370. Specifically, the p+ ohmic contacts 370 or 365 may be similar to the p+ ohmic contacts 220 in FIG. 2.

FIG. 4 depicts a specific example of a stack 400, which may be similar to stack 200 of FIG. 2. Specifically, the stack 400 may include an n+ contact layer 405, and n− varactor layers 410 and 425, which may be respectively similar to elements 205, 210, and 225 of FIG. 2. Similarly, the stack 400 may include one or more n+ ohmic contacts such as ohmic contacts 435 and 440, and one or more p+ ohmic contacts such as ohmic contacts 420, which may be similar to ohmic contacts 235, 240, and 220, respectively.

The p+ anode contact layer may be split in stack 400, with one or more etch stop layers positioned between the two layers of the p+ anode contact layers. As shown in FIG. 4, an etch stop layer 475, which may be a p+ etch stop layer, may be positioned between the top p+ anode contact layer 415, and the bottom p+ anode contact layer 417. Similarly, a bottom n+ contact layer may be split into two separate layers, with one or more etch stop layers such as n+ etch stop layers positioned therebetween. For example, in stack 400 the n+ contact layer may be split into an upper n+ contact layer 430, and a lower n+ contact layer 432. Etch stop layer 480 may be positioned between the two layers of the n+ contact layer.

In embodiments, one or more of the contact layers 405, 430, and 432; the varactor layers 410 and 425; and the anode contact layers 415 and 417 may be comprised of doped gallium arsenide. In embodiments, the etch stop layers 475 and 480 may be comprised of doped aluminum gallium arsenide or indium gallium phosphide.

FIG. 5 depicts a specific example of a stack 500, which may be similar to stack 300 of FIG. 3. Specifically, the stack 500 may include a p+ anode layer 545 and n− varactor layers 510 and 525, which may be respectively similar to elements 345, 310, and 325 of FIG. 3. Similarly, the stack 500 may include one or more n+ ohmic contacts 560, and p+ ohmic contacts 565 or 570, which may be respectively similar to ohmic contacts 360, 365, and 370 of FIG. 3.

The n+ contact layer may be split into two separate layers with an etch stop layer such as an n+ etch stop layer positioned therebetween. As shown in FIG. 5, stack 500 may include a top n+ contact layer 550, and a bottom n+ contact layer 552, with etch stop layer 575 positioned therebetween. Etch stop layer 575 may be similar to etch stop layer 475 of FIG. 4.

Similarly, a bottom p+ anode layer of stack 500 may be split into two separate layers, with an etch stop layer such as a p+ etch stop layer positioned therebetween. Specifically, the p+ anode layer may be split into a top p+ anode layer 555, and a bottom p+ anode layer 557, with etch stop layer 580 positioned therebetween. Etch stop layer 580 may be similar to etch stop layer 480 of FIG. 4.

In embodiments, one or more of the contact layers 550 and 552; the varactor layers 525 and 510; and the anode layers 545, 555, and 557 may be comprised of gallium arsenide.

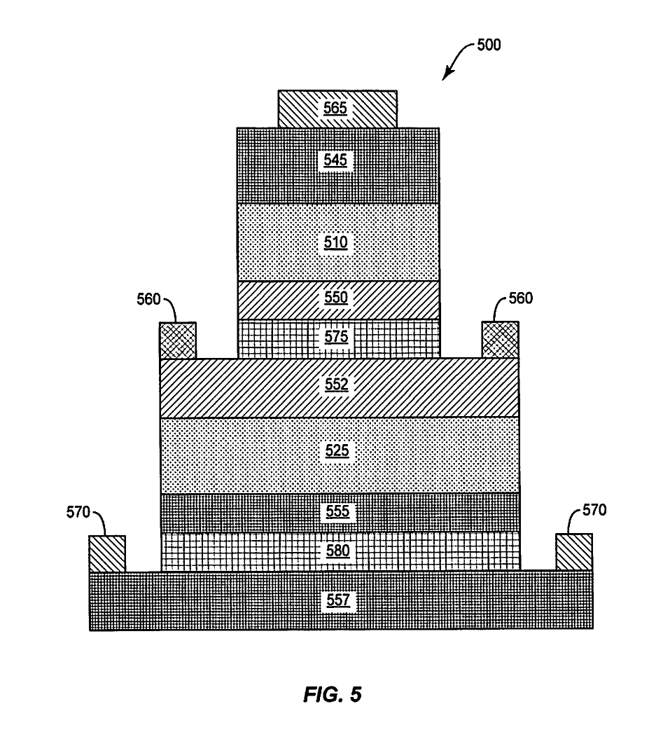

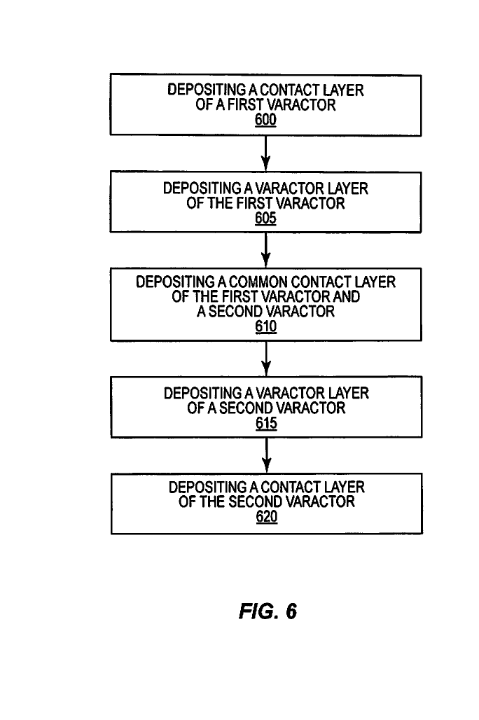

FIG. 6 depicts an example method for forming a stack such as stacks 200, 300, 400, or 500. Specifically, a contact layer of a first varactor may be deposited at 600. The contact layer may be, for example, p+ anode layers 355, 555, 557.

Alternatively, the contact layer may be, for example, n+ contact layers 230, 430, or 432. Specifically, the type of contact layer may be selected based on whether stack 200, 300, 400, or 500 is being constructed. In some embodiments, the deposition of the contact layer may include deposition of an etch stop layer such as etch stop layers 480 or 580.

Next, a varactor layer of the first varactor may be deposited at 605. Specifically, the varactor layer may be an n− varactor layer such as layers 225, 325, 425, or 525. After depositing the varactor layer, the process may involve depositing a common contact layer of the first varactor and a second varactor at 610. The common contact layer may be, for example p+ anode layers 215, 415, or 417. Alternatively, the common contact layer may be n+ contact layers 350, 550, or 552. Specifically, the common contact layer may be selected based on whether stacks 200, 300, 400, or 500 are being constructed. In some embodiments, deposition of the common contact layer may involve deposition of an etch stop layer such as etch stop layers 475 or 575.

Subsequent to deposition of the common contact layers at 610, the process may next involve depositing a varactor layer of a second varactor layer at 615. Specifically, the second varactor layer may be an n− varactor layer such as layers 210, 310, 410, or 510. Finally, the process may involve depositing a contact layer of the second varactor at 620. Specifically, the contact layer may be an n+ contact layer such as layers 205 or 405. In other embodiments, the second contact layer may be a p+ anode layer such as layers 345 or 545. Specifically, the type of contact layer may be selected based on whether stack 200, 300, 400, or 500 is being constructed.

In some embodiments, the process may involve additional or alternative steps. For example, in some embodiments, ohmic contacts may be deposited onto the stack. In other embodiments, one or more of the layers may be deposited in an order that is different from the order illustrated in FIG. 6. For example, in some embodiments two layers may be deposited in parallel with one another.

Stacks 200, 300, 400, or 500 may be incorporated into a variety of systems. A block diagram of an example system 700 is illustrated in FIG. 7. As illustrated, the system 700 includes a power amplifier (PA) module 702, which may be a radio frequency (RF) PA module in some embodiments. The system 700 may include a transceiver 704 coupled with the PA module 702 as illustrated. The PA module 702 may include one or more of stacks 200, 300, 400, or 500. In various embodiments, the stacks 200, 300, 400, or 500 may additionally/alternatively be included in the transceiver 704 to provide, e.g., up-converting, or in an antenna switch module (ASM) 706 to provide various switching functions.

The PA module 702 may receive an RF input signal, RFin, from the transceiver 704. The PA module 702 may amplify the RF input signal, RFin, to provide the RF output signal, RFout. The RF input signal, RFin, and the RF output signal, RFout, may both be part of a transmit chain, respectively noted by Tx-RFin and Tx-RFout in FIG. 7.

The amplified RF output signal, RFout, may be provided to the ASM 706, which effectuates an over-the-air (OTA) transmission of the RF output signal, RFout, via an antenna structure 708. The ASM 706 may also receive RF signals via the antenna structure 708 and couple the received RF signals, Rx, to the transceiver 704 along a receive chain.

In various embodiments, the antenna structure 708 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 700 may be suitable for any one or more of terrestrial and satellite communications, radar systems, and possibly in various industrial and medical applications. More specifically, in various embodiments, the system 700 may be a selected one of a radar device, a satellite communication device, a mobile computing device (e.g., a phone, a tablet, a laptop, etc.), a base station, a broadcast radio, or a television amplifier system.

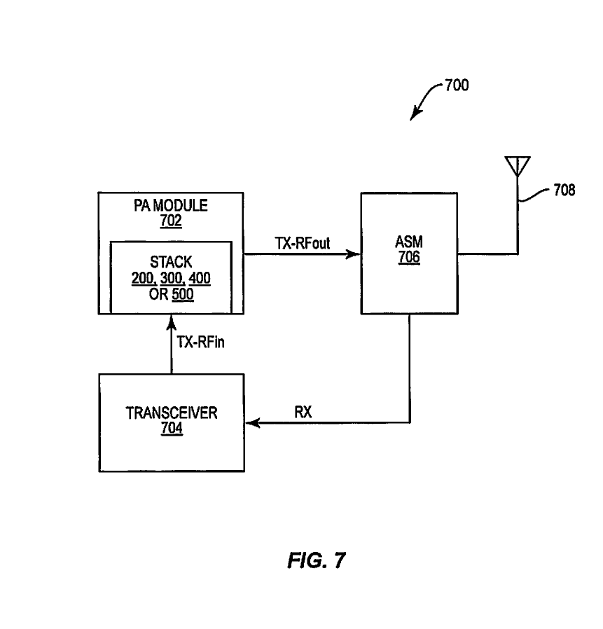

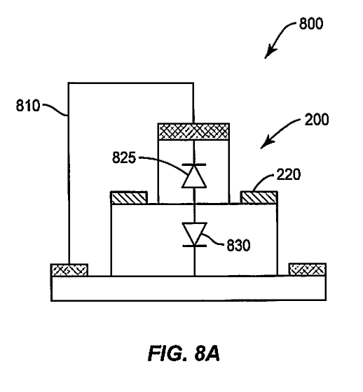

FIG. 8a illustrates a multi-varactor module 800 as a further embodiment of the stack 200 of FIG. 2. An intra-connect structure 810 may electrically couple the cathode of the lower varactor 830 with the cathode of the upper varactor 825 forming a multi-varactor module (or parallel varactor pair). In other embodiments, the stack 400 of FIG. 4 having etch stop layers may be used to form the multi-varactor module 800. This parallel varactor arrangement may reduce overall die area up to approximately 50% over a single varactor epitaxial stack. This arrangement may also be useful when a large number of varactors are required on a single substrate.

FIGS. 8b and 8c illustrate the epitaxial layers of the stack 200 formed on a substrate 805. The substrate 805 may be constructed of a semiconductor material that is relatively inert with respect to the stack 200. The substrate 805 may be an undoped or lightly doped semiconductor material having a relatively high resistivity. The intra-connect structure 810 may electrically couple the ohmic contact 240 of the lower varactor 830 to the ohmic contact 235 of the upper varactor 825 to form a common cathode port of the multi-varactor module 800. The intra-connect structure 810 may be constructed of surface metallization, bond wiring, or other semiconductor wiring structures or any combination thereof that is suitable for electrical coupling of the ohmic contacts. The ohmic contacts 220 may form a common anode port of the multi-varactor module 800. The varactor layer 210 may occupy as much as 90% die area as compared to a die area of the anode layer 215 and varactor layer 225. The larger die area of the anode layer 215 may be needed to form the ohmic contact 220. Using this ratio, a 47% reduction in die area is achievable over implementing the equivalent capacitance in a single varactor epitaxial stack. Other improvements may be an improvement in the Quality (or Q) factor by reducing the die area in the propagation direction. For example, if the die area is reduced by 50% the Q may increase by a factor of two. Additionally, with parallel ohmic contacts 235 and 240 resistance losses are reduced, thus further increasing the Q factor.

In other embodiments the varactor layer 210 may reside over a die area that is approximately 33% of a die area of the anode layer 215 and the varactor layer 225. Using this ratio, a 25% reduction in die area may be achievable over implementing the equivalent capacitance in a single varactor epitaxial stack.

FIGS. 8d and 8e illustrate schematic representations of multi-varactor module 800. The parallel varactor pair of FIG. 8d may be represented as a single varactor diode as depicted in FIG. 8e. For a given tuning voltage, the capacitance of the upper varactor 825 and the capacitance of the lower varactor 830 may be summed to determine a total capacitance provided between the common anode port and the common cathode port for the multi-varactor module 800.

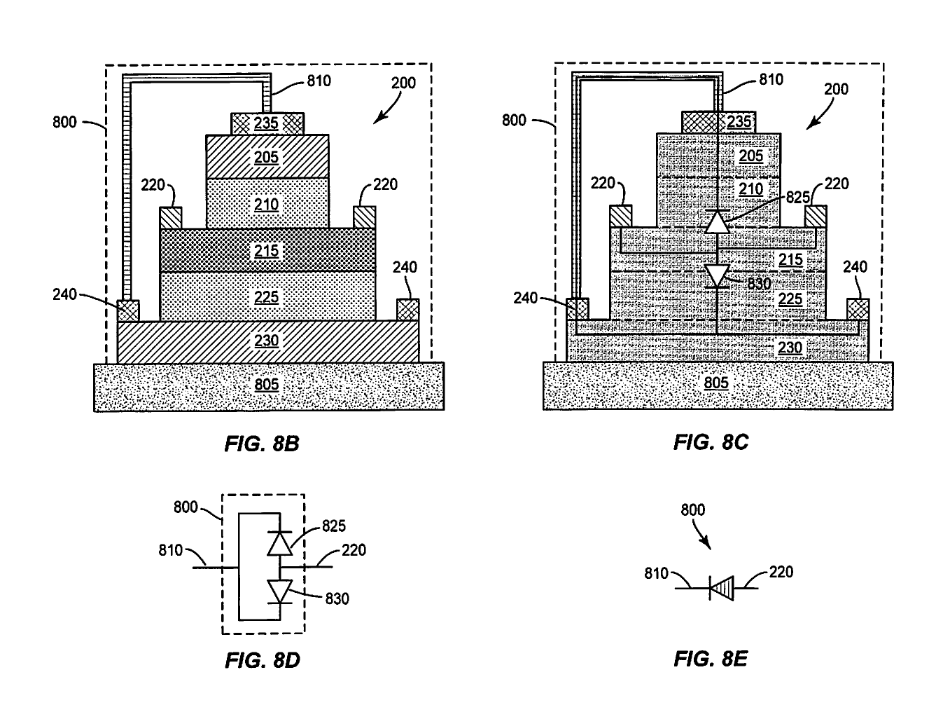

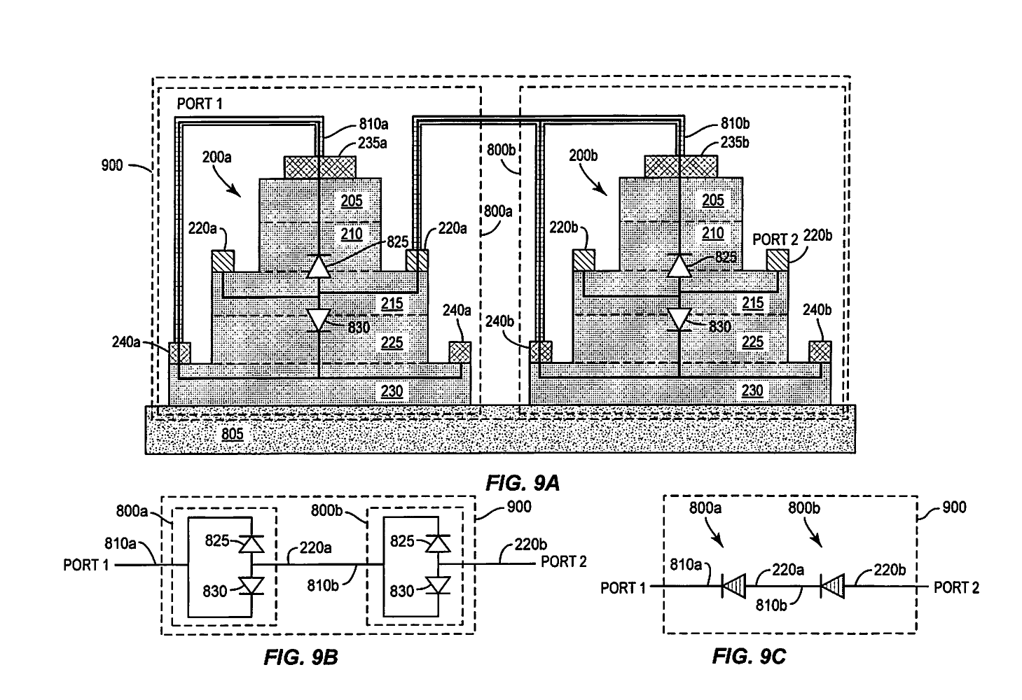

FIG. 9a illustrates a multi-varactor assembly 900 which includes a first multi-varactor module 800a and a second multi-varactor module 800b formed on the substrate 805. An intra-connect structure 810b of the second multi-varactor module 800b may be extended to electrically couple to the ohmic contact 220a of the first multi-varactor module 800a. An intra-connect structure 810a of the first multi-varactor module 800a forms a first port (Port 1) of the multi-varactor assembly 900 and the ohmic contact 220b of the second multi-varactor module 800b forms a second port (Port 2) of the multi-varactor assembly 900.

FIGS. 9b and 9c illustrate schematic representations of the multi-varactor assembly 900, wherein the first multi-varactor module 800a may be electrically coupled in a front to back configuration with the second multi-varactor module 800b.

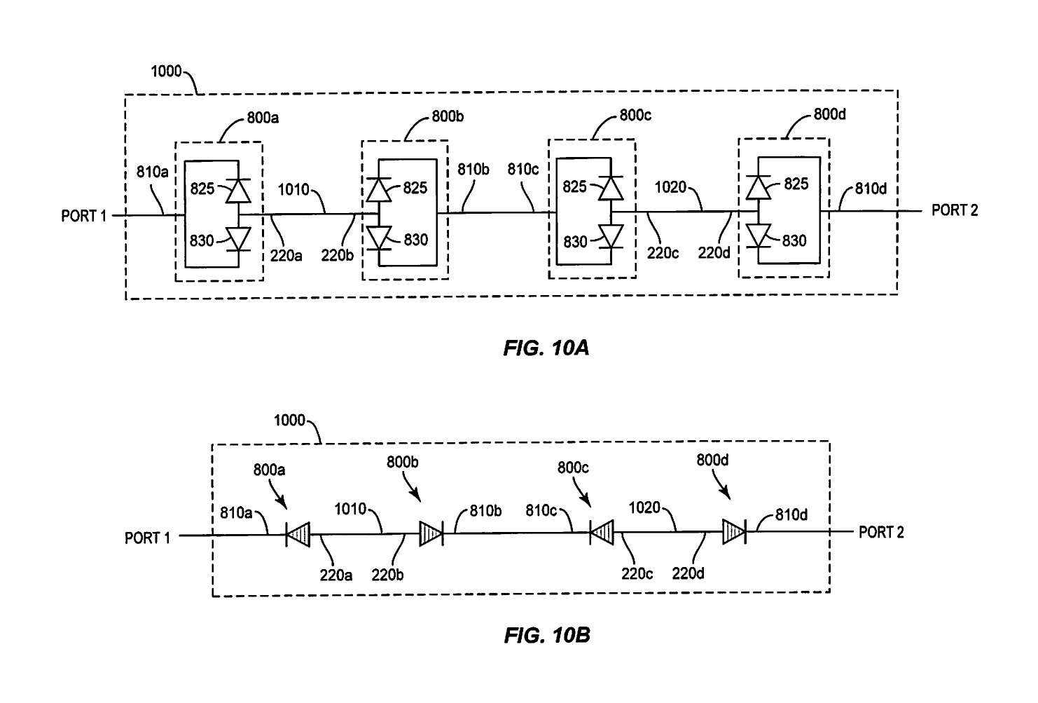

FIGS. 10a and 10b illustrate schematic representations of a multi-varactor assembly 1000 comprised of four multi-varactor modules 800a-800d coupled in a back to back (anode to anode) and front to front (cathode to cathode) configuration. A first multi-varactor assembly port (Port 1) may be formed by an intra-connect structure 810a of the first multi-varactor module 800a. An inter-connect structure 1010 may electrically couple ohmic contacts 220a and 220b of the first and second multi-varactor modules 800a and 800b. An intra-connect structure 810b of the second multi-varactor module 800b may electrically couple to an intra-connect structure 810c of the third multi-varactor module 800c. An inter-connect structure 1020 may electrically couple ohmic contacts 220c and 220d of the third and fourth multi-varactor modules 800c and 800d. Both inter-connect structures 1010 and 1020 may be constructed of surface metallization, bond wiring, or other semiconductor wiring structures or any combination thereof that is suitable for electrical coupling of the ohmic contacts. A second multi-varactor assembly port (Port 2) may be formed by an intra-connect structure 810d of the fourth multi-varactor module 800d.

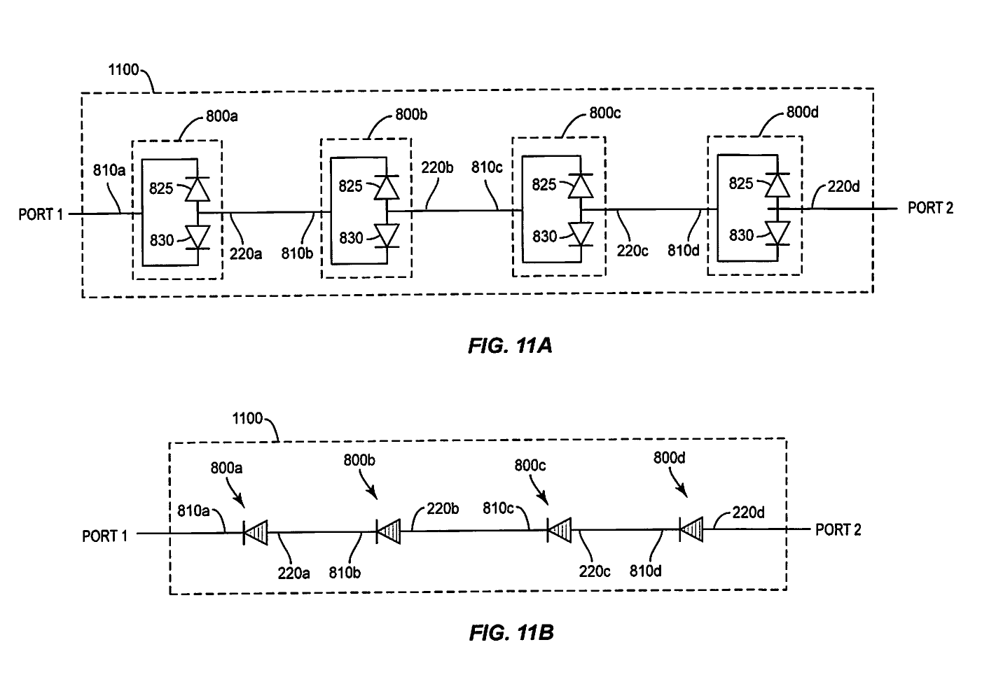

FIGS. 11a and 11b illustrate schematic representations of a multi-varactor assembly 1100 comprised of four multi-varactor modules 800a-800d coupled in a back to front (anode to cathode) configuration. A first multi-varactor assembly port (Port 1) may be formed by an intra-connect structure 810a of the first multi-varactor module 800a. An intra-connect structure 810b of the second multi-varactor structure 800b may electrically couple to a ohmic contact 220a of the first multi-varactor module 800a. An intra-connect structure 810c of the third multi-varactor module 800c may electrically couple to an ohmic contact 220b of the second multi-varactor module 800b. An intra-connect structure 810d of the fourth multi-varactor module 800d may electrically couple to an ohmic contact 220c of the third multi-varactor module 800c. A second multi-varactor assembly port (Port 2) may be formed by an ohmic contact 220d of the fourth multi-varactor module 800d.

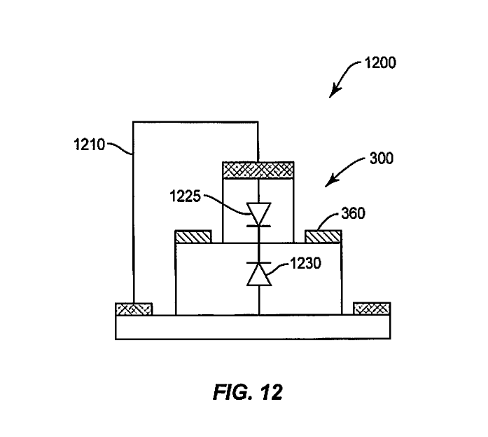

FIG. 12 illustrates a multi-varactor module 1200 as a further embodiment of the dual varactor epitaxial stack 300 of FIG. 3. An intra-connect structure 1210 may electrically couple the anode of the lower varactor 1230 with the anode of the upper varactor 1225 forming a parallel varactor pair. The intra-connect structure 1210 may form a common anode port and the ohmic contact 360 may form a common cathode port of the multi-varactor module 1200.

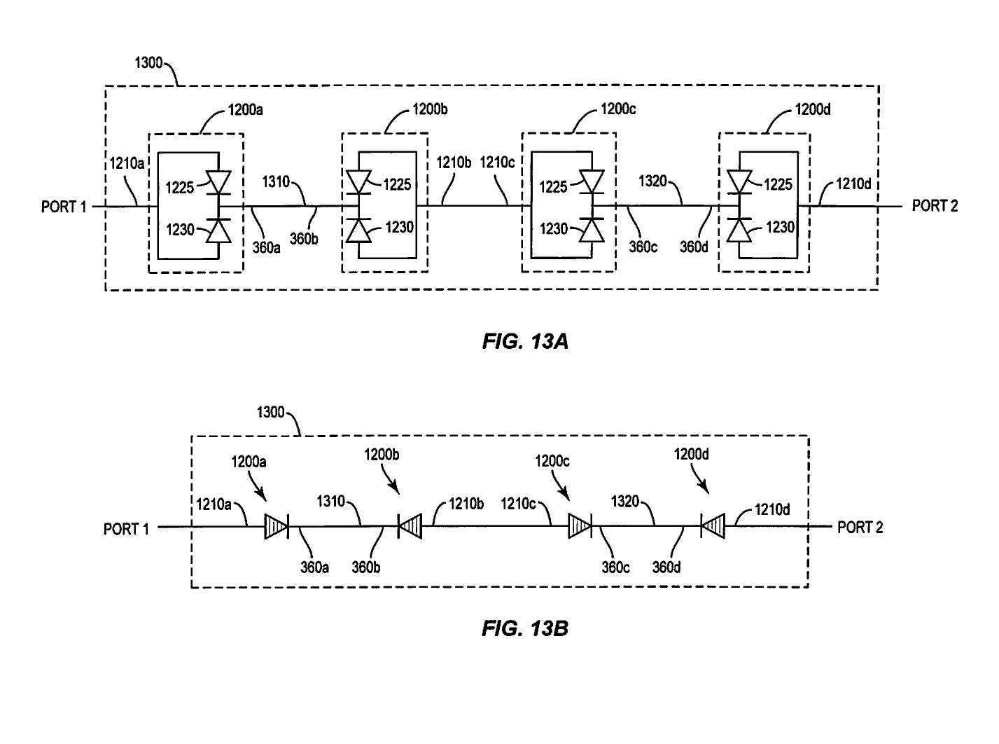

FIGS. 13a and 13b illustrate schematic representations of a multi-varactor assembly 1300 comprised of a plurality of multi-varactor modules 1200a-1200d coupled in a front to front (cathode to cathode) and back to back (anode to anode) configuration. A first multi-varactor assembly port (Port 1) may be formed by an intra-connect structure 1210a of the first multi-varactor module 1200a. An inter-connect structure 1310 may electrically couple contacts 360a and 360b of the first and second multi-varactor modules 1200a and 1200b. An intra-connect structure 1210b of the second multi-varactor module 1200b may electrically couple to an intra-connect structure 1210c of the third multi-varactor module 1200c. An inter-connect structure 1320 may electrically couple contacts 360c and 360d of the third and fourth multi-varactor modules 1200c and 1200d. Both inter-connect structures 1310 and 1320 may be constructed of surface metallization, bond wiring, or other semiconductor wiring structures or any combination thereof that is suitable for electrical coupling of the contacts 360a-360d. A second multi-varactor assembly port (Port 2) may be formed by an intra-connect structure 1210d of the fourth multi-varactor module 1200d. In some embodiments, it may be desirable for the multi-varactor assembly to have a greater or lesser number of multi-varactor modules.

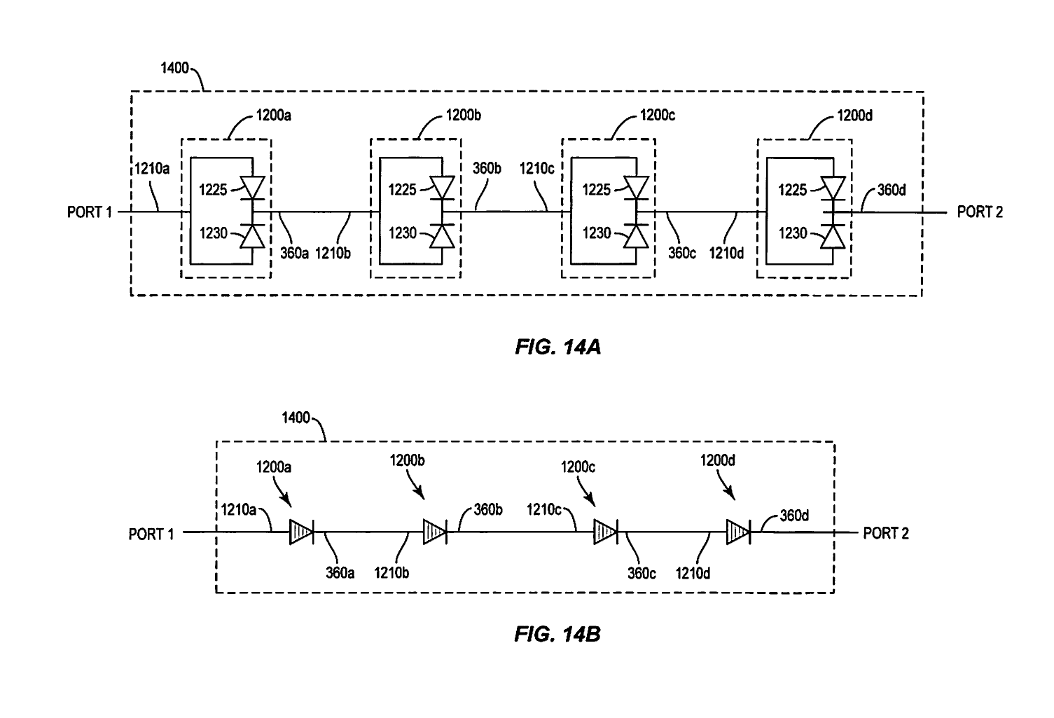

FIGS. 14a and 14b illustrate schematic representations of a multi-varactor assembly 1400 comprised of a plurality of multi-varactor modules 1200a-1200d coupled in a front to back (cathode to anode) configuration. A first multi-varactor assembly port (Port 1) may be formed by an intra-connect structure 1210a of the first multi-varactor module 1200a. An intra-connect structure 1210b of the second multi-varactor structure 1200b may electrically couple to an contact 360a of the first multi-varactor module 1200a. An intra-connect structure 1210c of the third multi-varactor module 1200c may electrically couple to an contact 360b of the second multi-varactor module 1200b. An intra-connect structure 1210d of the fourth multi-varactor module 800d may electrically couple to an contact 360c of the third multi-varactor module 1200c. A second multi-varactor assembly port (PORT2) may be formed by contact 360d of the fourth multi-varactor module 1200d.

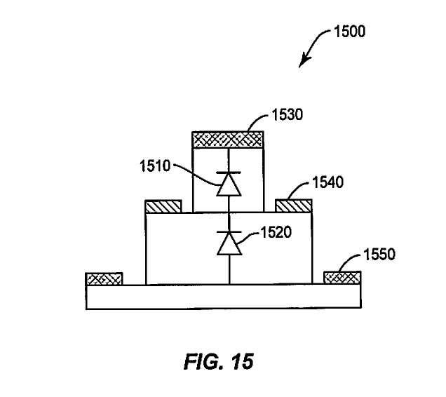

FIG. 15 illustrates a dual varactor epitaxial stack 1500 as a further embodiment of a dual varactor epitaxial stack in a front to back (cathode to anode) configuration. The dual varactor epitaxial stack 1500 may be configured as shown in FIG. 5b of U.S. Provisional Patent Application No. 62/174,573, entitled “DUAL-SERIES VARACTOR EPI.” In other embodiments, the cathode of the lower varactor 1520 may be coupled within the dual varactor epitaxial stack 1500 with an anode of the upper varactor 1510. An ohmic contact 1550 may be formed on a lower layer electrically coupling to the anode of the lower varactor 1520. An ohmic contact 1540 may be formed on a middle layer electrically coupling to the cathode of the lower varactor 1520 and the anode of the upper varactor 1510. An upper varactor layer may reside over a die area between 33% and 90% of a lower varactor layer die area thus allowing the surface area needed on a middle layer for the ohmic contact 1540. Another ohmic contact 1530 may be formed on an upper layer electrically coupling to the cathode of the upper varactor 1510.

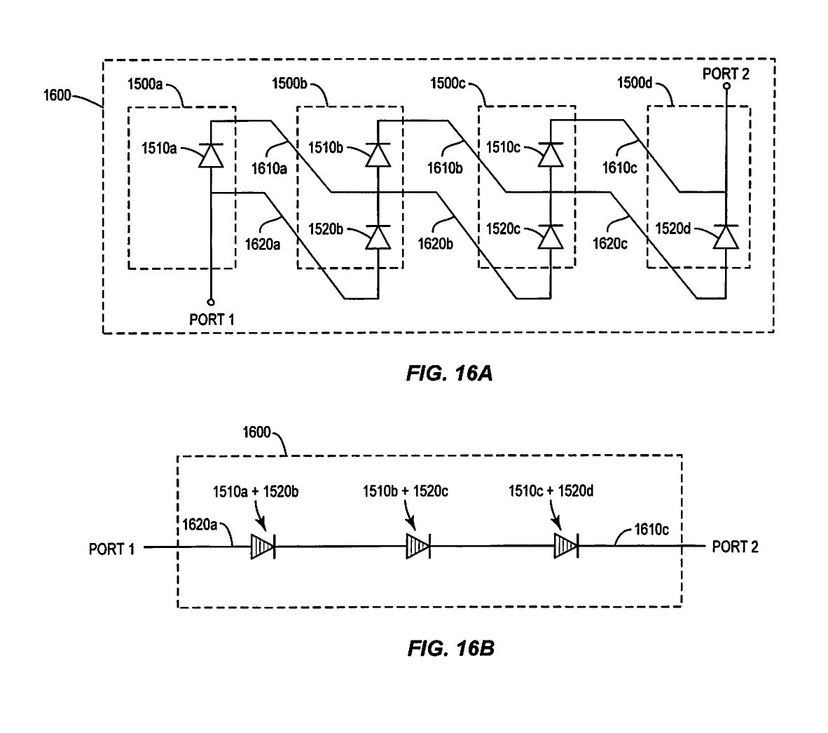

FIGS. 16a and 16b illustrate schematic representations of a multi-varactor assembly 1600 comprised of a plurality of dual varactor epitaxial stacks 1500a-1500d coupled in a front to back (cathode to anode) configuration. More specifically, upper varactors may be electrically coupled in parallel to lower varactors of adjacent stacks. An upper varactor 1510a of a first dual varactor stack 1500a may be electrically coupled in parallel with a lower varactor 1520b of a second dual varactor stack 1500b with inter-connect structures 1610a and 1620a. A first multi-varactor assembly port (Port 1) may be formed by the inter-connect structure 1620a. An upper varactor 1510b of the second dual varactor stack 1500b may be electrically coupled in parallel with a lower varactor 1520c of a third dual varactor stack 1500c with inter-connect structures 1610b and 1620b. Likewise an upper varactor 1510c of the third dual varactor stack 1500c may be electrically coupled in parallel with a lower varactor 1520d of a fourth dual varactor stack 1500d with inter-connect structures 1610c and 1620d. A second multi-varactor assembly port (Port 2) may be formed by the inter-connect structure 1610c. Inter-connect structures 1610a-1610c and 1620a-1620c may be constructed of surface metallization, bond wiring, or other semiconductor wiring structures or any combination thereof that is suitable for electrical coupling of the ohmic contacts. In some embodiments, it may be desirable for the multi-varactor assembly to have a greater or lesser number of dual varactor epitaxial stacks 1500a-1500d.

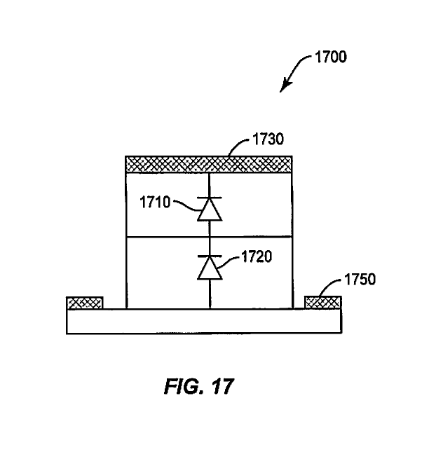

FIG. 17 illustrates a dual varactor epitaxial stack 1700 as a further embodiment of a dual varactor epitaxial stack in a front to back (cathode to anode) configuration wherein an upper varactor layer die area may be between 90% and 100% of a lower varactor layer die area. In this embodiment an ohmic contact is not formed on a middle layer. An ohmic contact 1750 may be formed on a lower layer electrically coupling to the anode of the lower varactor 1720 and an ohmic contact 1730 may be formed on an upper layer electrically coupling to the cathode of the upper varactor 1710.

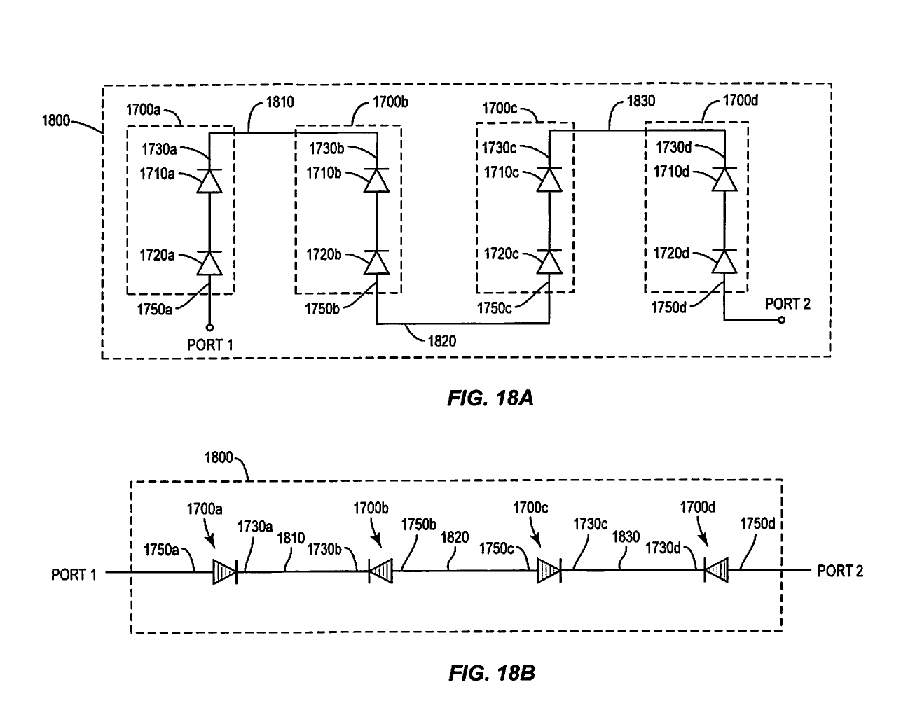

FIGS. 18a and 18b illustrate schematic representations of a multi-varactor assembly 1800 comprised of a plurality of dual varactor epitaxial stacks 1700a-1700d coupled in a front to front (cathode to cathode) and back to back (anode to anode) configuration. A first multi-varactor assembly port (Port 1) may be formed by a lower layer ohmic contact 1750a of the first epitaxial stack 1700a. A first inter-connect structure 1810 may electrically couple upper layer ohmic contacts 1730a and 1730b of the first and second dual varactor epitaxial stacks 1700a and 1700b. A second inter-connect structure 1820 may electrically couple lower layer ohmic contacts 1750b and 1750c of the second and third dual varactor epitaxial stacks 1700b and 1700c. A third inter-connect structure 1830 may electrically couple upper layer ohmic contacts 1730c and 1730d of the third and fourth dual varactor epitaxial stacks 1700c and 1700d. Inter-connect structures 1810, 1820, and 1830 may be constructed of surface metallization, bond wiring, or other semiconductor wiring structures or any combination thereof that is suitable for electrical coupling of the ohmic contacts. A second multi-varactor assembly port (Port 2) may be formed by a lower layer ohmic contact 1750d of the fourth dual varactor epitaxial stack 1700d.

In an alternate embodiment, the second and third dual varactor epitaxial stacks 1700b and 1700c may have a common lower contact layer (not shown). The common lower contact layer would directly couple the lower varactors 1720a and 1720b, thus eliminating the second inter-connect structure. In other embodiments, it may be desirable for the multi-varactor assembly to have a greater or lesser number of dual varactor epitaxial stacks 1700a-1700d.

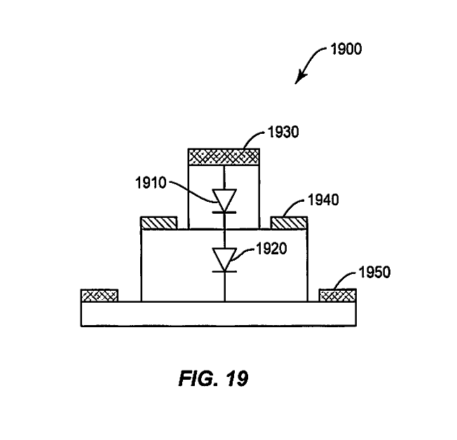

FIG. 19 illustrates a dual varactor epitaxial stack 1900 as a further embodiment of a dual varactor epitaxial stack in a back to front (anode to cathode) configuration. The multi-varactor module 1900 may be configured as shown in FIG. 5a of U.S. Patent Provisional Application No. 62/174,573, entitled “DUAL-SERIES VARACTOR EPI. In other embodiments, an anode of a lower varactor 1920 may be coupled within the dual varactor epitaxial stack 1900 with a cathode of an upper varactor 1910. An ohmic contact 1950 may be formed on a lower layer electrically coupling to the cathode of the lower varactor 1920. An ohmic contact 1940 may be formed on a middle layer electrically coupling to the anode of the lower varactor 1920 and the cathode of the upper varactor 1910. An upper varactor layer may reside over a die area between 33% and 90% of a lower varactor layer die area thus allowing the surface area needed on a middle layer for the ohmic contact 1940. Another ohmic contact 1930 may be formed on an upper layer electrically coupling to the cathode of the upper varactor 1910.

In some embodiments for FIGS. 8a, 8b, 8c, 12, 15, 17, and 19 the upper varactor layer may reside over a die area that is between 25% and 50% of a die area for the lower varactor. In other embodiments, the upper varactor layer may reside over a die area that is between 50% and 95% of a die area for the lower varactor.

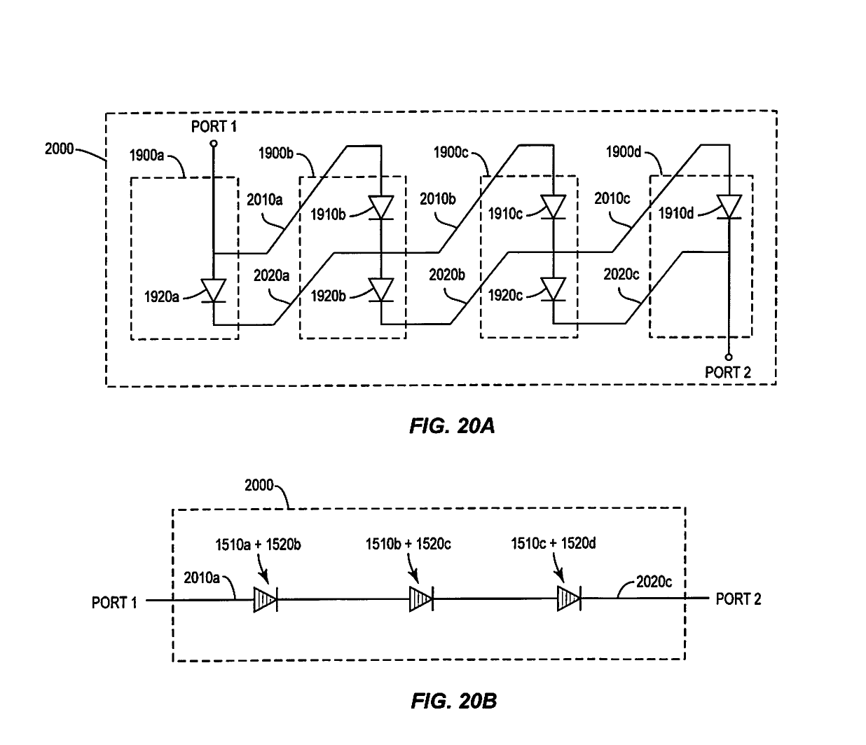

FIGS. 20a and 20b illustrate schematic representations of a multi-varactor assembly 2000 comprised of a plurality of dual varactor epitaxial stacks 1900a-1900d coupled in a front to back (cathode to anode) configuration. More specifically, lower varactors may be electrically coupled in parallel to upper varactors of adjacent dual varactor epitaxial stacks. A lower varactor 1920a of a first dual varactor epitaxial stack 1900a may be electrically coupled in parallel with an upper varactor 1910b of a second dual varactor epitaxial stack 1500b with inter-connect structures 2010a and 2020a. A first multi-varactor assembly port (Port 1) may be formed by the inter-connect structure 2010a. A lower varactor 1920b of the second dual varactor epitaxial stack 1900b may be electrically coupled in parallel with an upper varactor 1910c of a third dual varactor epitaxial stack 1900c with inter-connect structures 2010b and 2020b. Likewise a lower varactor 1920c of the third stack 1900c may be electrically coupled in parallel with an upper varactor 1910d of a fourth dual varactor epitaxial stack 1900d with inter-connect structures 2010c and 2020d. A second multi-varactor assembly port (Port 2) may be formed by the inter-connect structure 2020c. Inter-connect structures 2010a-2010c and 2020a-2020c may be constructed of surface metallization, bond wiring, or other semiconductor wiring structures or any combination thereof that is suitable for electrical coupling of the ohmic contacts. In some embodiments, it may be desirable for the multi-varactor assembly to have a greater or lesser number of dual varactor epitaxial stacks 1900a-1900d.

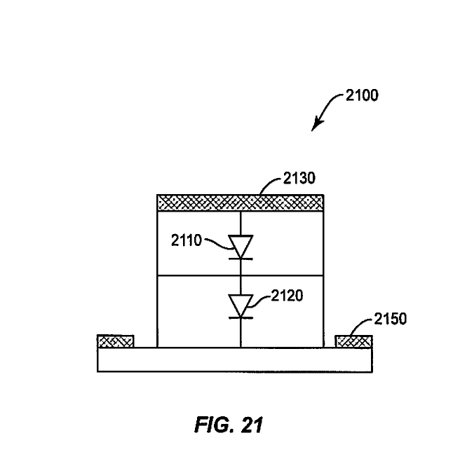

FIG. 21 illustrates a dual varactor epitaxial stack 2100 as a further embodiment of a dual varactor epitaxial stack in a back to front (anode to cathode) configuration wherein an upper varactor layer die area may be between 90% and 100% of a lower varactor layer die area. In this embodiment an ohmic contact is not formed on a middle layer. An ohmic contact 2150 may be formed on a lower layer electrically coupling to the cathode of the lower varactor 2120 and an ohmic contact 2130 may be formed on an upper layer electrically coupling to the anode of the upper varactor 2110.

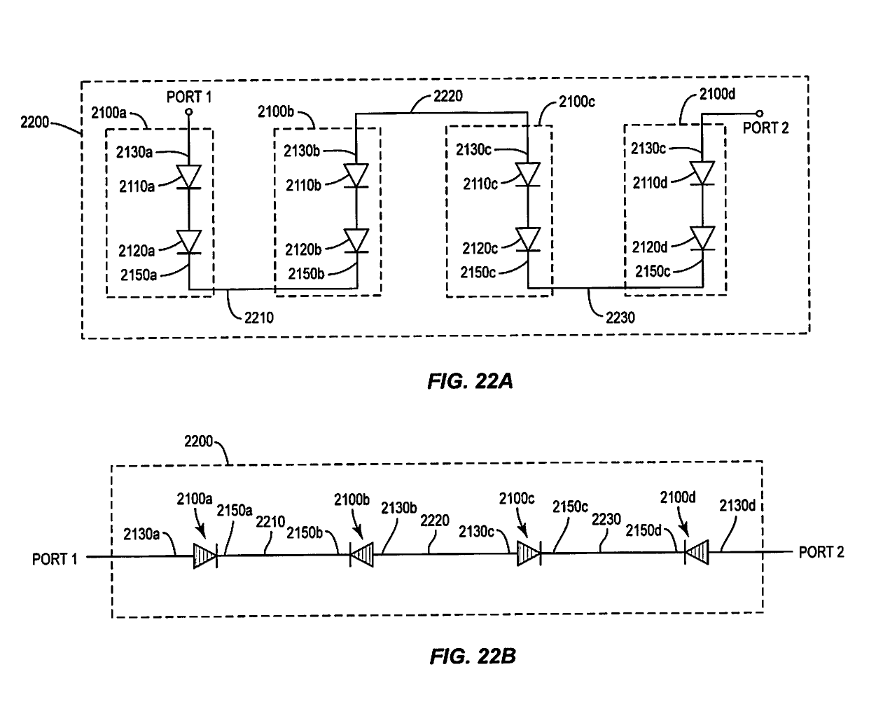

FIGS. 22a and 22b illustrate schematic representations of a multi-varactor assembly 2200 comprised of a plurality of dual varactor epitaxial stacks 2100a-2100d coupled in a front to front (cathode to cathode) and back to back (anode to anode) configuration. A first multi-varactor assembly port (Port 1) may be formed by an upper layer ohmic contact 2130a of the first dual varactor epitaxial stack 2100a. A first inter-connect structure 2210 may electrically couple lower layer ohmic contacts 2150a and 2150b of the first and second epitaxial stacks 2100a and 2100b. A second inter-connect structure 2220 may electrically couple upper layer ohmic contacts 2130b and 2130c of the second and third dual varactor epitaxial stacks 2100b and 2100c. A third inter-connect structure 2230 may electrically couple lower layer ohmic contacts 2150c and 2150d of the third and fourth dual varactor epitaxial stacks 2100c and 2100d. Inter-connect structures 2210, 2220, and 2230 may be constructed of surface metallization, bond wiring, or other semiconductor wiring structures or any combination thereof that is suitable for electrical coupling of the ohmic contacts. A second multi-varactor assembly port (Port 2) may be formed by an upper layer ohmic contact 2130d of the fourth dual varactor epitaxial stack 2100d.

In an alternate embodiment, the first and second dual varactor epitaxial stacks 2100a and 2100b may have a common lower contact layer (not shown). The common lower contact layer would directly couple the lower varactors 2120a and 2120b, thus eliminating the first inter-connect structure. Likewise, the third and fourth dual varactor epitaxial stacks 2100c and 2100d may have a common lower contact layer (not shown). The common lower contact layer would directly couple the lower varactors 2120c and 2120d, thus eliminating the third inter-connect structure. In other embodiments, it may be desirable for the multi-varactor assembly 2200 to have a greater or lesser number of dual varactor epitaxial stacks 2100a-2100d.

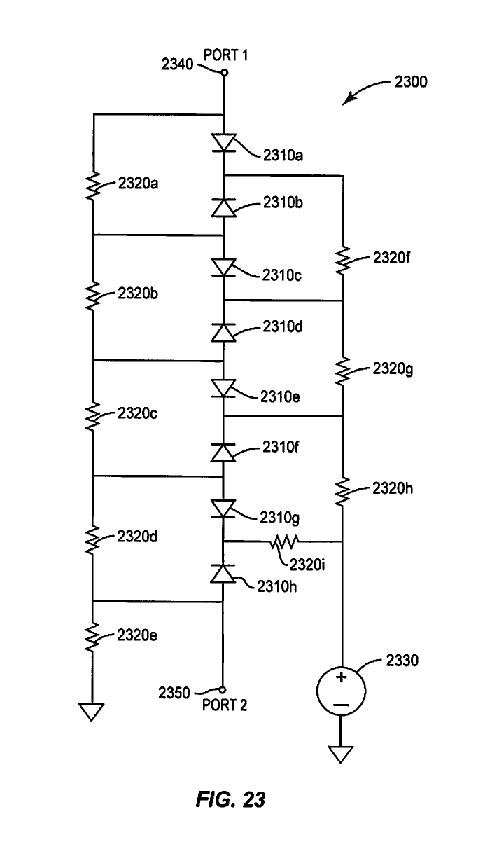

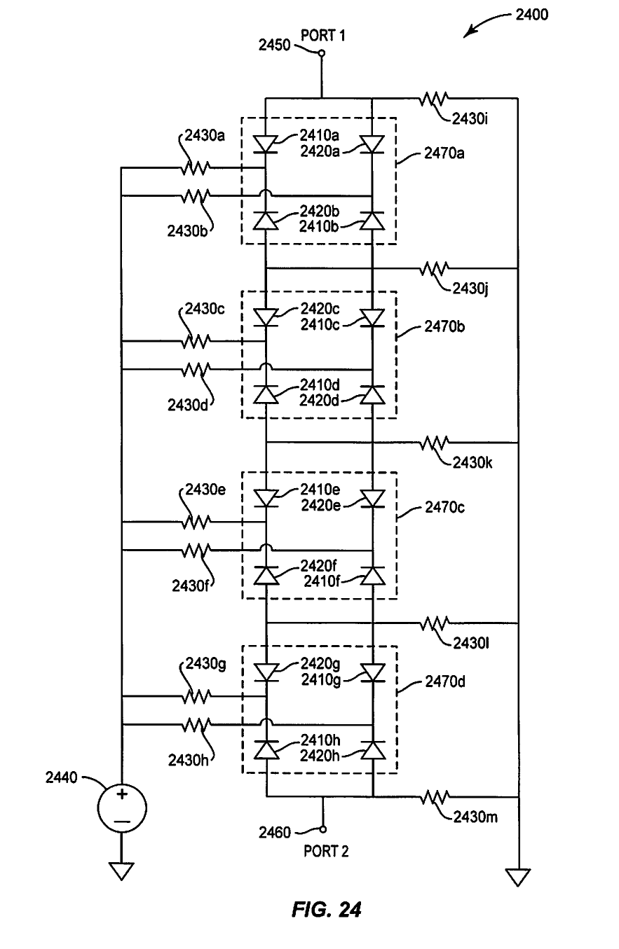

FIG. 23 illustrates an example of an alternate compound varactor 2300 having a single varactor stack, in accordance with various embodiments. Specifically, the compound varactor 2300 may include a plurality of varactors 2310a-2310h (collectively varactors 2310) generally positioned between a “Port 1” 2340 and a “Port 2” 2350. Resistors 2320a-2320i (collectively resistors 2320) may provide a reverse bias voltage to each of the varactors 2310. The back sides (or anodes) of the varactors 2310 may be coupled to ground with the series resistors 2320a-2320e. The front sides (or cathodes) of the varactors 2310 may be coupled to a DC power source 2330 with series resistors 2320f-2320i. The resistors 2320 may provide a parallel feed such that a reverse bias voltage provided by the DC power source 2330 is independent of the number of varactors in the single varactor stack. RF voltages applied between “Port 1” 2340 and “Port 2” 2350 may alternate in polarity between the varactors 2310 such that self-modulation effects are reduced. For example, as the RF voltage across the varactor 2310a increases the RF voltage across varactor 2310b decreases. This results in a cancellation of overall capacitance change for the varactors due to RF voltage swing. Other more complicated circuits may be envisioned having multiple DC power sources that may each supply different or similar positive or negative voltages, or multiple ground connections.

The varactors 2310 may comprise any applicable combination of previously described dual varactor epitaxial stacks or multi-varactor modules. For example, varactors 2310a and 2310b may comprise the front to front configured varactors of the stack 300 of FIG. 3 or the stack 500 of FIG. 5. In other embodiments, each of the varactors 2310 may comprise a multi-varactor module 800 of FIG. 8a or a multi-varactor module 1200 of FIG. 12. In some embodiments varactors 2310 may have equal die areas (or capacitance to voltage tuning characteristics). In other embodiments, die areas may be different for improved performance characteristics.

FIG. 24 illustrates an example of an alternate compound varactor 2400 having dual asymmetric varactor stacks, in accordance with various embodiments. Specifically, the compound varactor 2400 may include a plurality of varactors, such as varactors 2410a-2410h (collectively varactors 2410) and varactors 2420a-2420h (collectively varactors 2420). A die area of each varactor 2410 may be three times as large as a die area of each varactor 2420. In other embodiments the die area ratio may be greater or less than 3-to-1. This die area ratio may be selected to reduce intermodulation distortion effects.

Varactors 2410 and 2420 may be generally positioned in two stacks in a back to front configuration between a “Port 1” 2450 and a “Port 2” 2460. A first anti-series/anti-parallel configuration 2470a may be comprised of varactors 2410a, 2410b, 2420a, and 2420b. A second anti-series/anti-parallel configuration 2470b may be comprised of varactors 2410c, 2410d, 2420c, and 2420d. A third anti-series/anti-parallel configuration 2470c may be comprised of varactors 2410e, 2410f, 2420e, and 2420f. A fourth anti-series/anti-parallel configuration 2470d may be comprise of 2410g, 2410h, 2420g, and 2420h. The first, second, third, and fourth anti-series/anti-parallel configurations 2470a-d may be coupled in series within the two stacks. In other embodiments, it may be desirable for the alternate compound varactor 2400 to have a greater or lesser number of anti-series/anti-parallel configurations. Parallel resistors 2430a-2430h may couple front side (or cathodes) of varactors 2410 and 2420 to a DC power source 2440. Parallel resistors 2430i-2430m may couple back side (or anodes) of varactors 2410 and 2420 to a circuit ground. Other more complicated circuits may be envisioned having multiple DC power sources 2440 that may each supply different or similar positive or negative voltages, or multiple ground connections.

The varactors 2410 and 2420 may comprise any applicable combination of previously described dual varactor epitaxial stacks or multi-varactor modules. For example, varactors 2410a and 2420b may comprise the front to front configured varactors of the stack 300 of FIG. 3 or the stack 500 of FIG. 5. If a capacitance to voltage tuning of varactor 2410a is three times that of varactor 2420b, then a die area reduction of up to 25% may be achieved over single varactor epitaxial stack configuration. In other embodiments, each of the varactors 2410 and 2420 may comprise the multi-varactor module 800 of FIG. 8a or the multi-varactor module 1200 of FIG. 12. This parallel varactor arrangement may reduce overall die area up to approximately 50% over a single varactor epitaxial stack configuration.

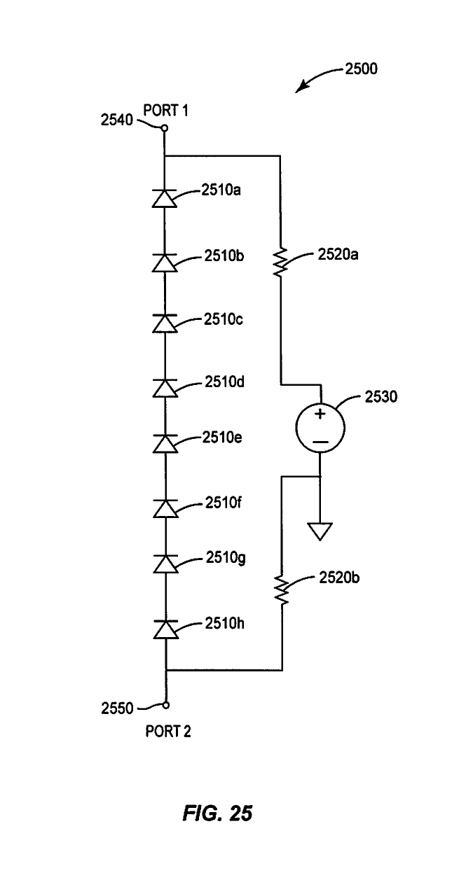

FIG. 25 illustrates another example of an alternate compound varactor 2500 having a single series of reversed biased varactors, in accordance with various embodiments. This configuration provides a much faster response time while requiring a higher reverse bias voltages than the circuits of FIG. 23 and FIG. 24. Specifically, the compound varactor 2500 may include a plurality of varactors 2510a-2510h (collectively varactors 2510) generally positioned in a back to front configuration between a “Port 1” 2540 and a “Port 2” 2550. The front side (or cathode) of the varactor 2510a may be coupled to a DC power source 2530 with a resistor 2520a. The back side (or anode) of the varactor 2510h may be coupled to ground with a resistor 2520b. Other more complicated circuits may be envisioned having multiple DC power sources that may each supply different or similar positive or negative voltages, or multiple ground connections.

The varactors 2510 may comprise any applicable combination of previously described dual varactor epitaxial stacks or multi-varactor modules. For example, varactors 2510a and 2510b may comprise the front to back configured varactors of the dual varactor epitaxial stack 1500 of FIG. 15 or the dual varactor epitaxial stack 1700 FIG. 17. In an alternate embodiment, varactors 2510a and 2510b may comprise the back to front configured varactors of the dual varactor epitaxial stack 1900 of FIG. 19 or the dual varactor epitaxial stack 2100 of FIG. 21. In other embodiments, each of the varactors 2510 may comprise the multi-varactor module 800 of FIG. 8a or the multi-varactor module 1200 of FIG. 12.

Although the present disclosure has been described in terms of the above-illustrated embodiments, it will be appreciated by those of ordinary skill in the art that a wide variety of alternate and/or equivalent implementations calculated to achieve the same purposes may be substituted for the specific embodiments shown and described without departing from the scope of the present disclosure. Those with skill in the art will readily appreciate that the teachings of the present disclosure may be implemented in a wide variety of embodiments. This description is intended to be regarded as illustrative instead of restrictive.

What is claimed is:

1. A semiconductor device comprising:
a substrate;
a lower contact layer positioned over the substrate;
a lower varactor layer positioned over the lower contact layer and having a first doping profile;
a common contact layer positioned over the lower varactor layer, wherein the lower contact layer, the lower varactor layer, and the common contact layer form a lower varactor;
an upper varactor layer positioned over the common contact layer and having a second doping profile that is inverted with respect to the first doping profile;
an upper contact layer positioned over the upper varactor layer, wherein the common contact layer, the upper varactor layer, and the upper contact layer form an upper varactor; and
a first intra-connect structure electrically coupling the lower contact layer and the upper contact layer such that the lower varactor and the upper varactor are placed in parallel and form a first multi-varactor module.

2. The semiconductor device of claim 1 wherein the common contact layer is a common anode layer for the upper and lower varactors.

3. The semiconductor device of claim 1 wherein the common contact layer is a common cathode layer for the upper and lower varactors.

4. The semiconductor device of claim 1 wherein the first intra-connect structure electrically couples to an upper ohmic contact positioned on the upper contact layer and electrically couples to a lower ohmic contact positioned on the lower contact layer.

5. The semiconductor device of claim 1 wherein the first intra-connect structure is a surface metallization structure.

6. The semiconductor device of claim 1 wherein the first intra-connect structure is a wire bond structure.

7. The semiconductor device of claim 1 wherein the first and second doping profiles are one of an abrupt profile, hyper-abrupt profile, or linear doping profile.

8. The semiconductor device of claim 1 wherein the lower varactor layer resides over a first area and the upper varactor layer resides over a second area, and the second area is between 25% and 50% of the first area.

9. The semiconductor device of claim 1 wherein the lower varactor layer resides over a first area and the upper varactor layer resides over a second area, and the second area is between 50% and 95% of the first area.

10. The semiconductor device of claim 1 wherein the common contact layer includes an upper common contact layer directly coupled with the upper varactor layer, and a lower common contact layer directly coupled with the lower varactor layer, and a common etch stop layer positioned between and directly coupled with the upper common contact layer and the lower common contact layer.

11. The semiconductor device of claim 1 wherein the lower contact layer comprises a top lower contact layer directly coupled with the lower varactor layer, and a bottom lower contact layer directly coupled with the substrate, and a lower etch stop layer directly coupled with and positioned between the top lower contact layer and the bottom lower contact layer.

12. The semiconductor device of claim 1 further comprising a second multi-varactor module positioned over the substrate and adjacent to the first multi-varactor module, wherein the first multi-varactor module is electrically coupled with the second multi-varactor module.

13. The semiconductor device of claim 1 wherein the upper and lower varactor layers are n− doped.

14. The semiconductor device of claim 2 wherein the common anode layer is p+ doped.

15. The semiconductor device of claim 3 wherein the common cathode layer is n+ doped.

16. The semiconductor device of claim 14 wherein the upper and lower contact layers are n+ doped.

17. The semiconductor device of claim 15 wherein the upper and lower contact layers are p+ doped.

18. The semiconductor device of claim 11 wherein adjacent layers of the first and second multi-varactor modules have essentially the same composition.

19. The semiconductor device of claim 1 further comprising a resistor coupled to the first intra-connect structure.

20. A semiconductor device comprising:
a substrate;
a first multi-varactor module comprising:
a first lower contact layer positioned over the substrate;
a first lower varactor layer positioned over the first lower contact layer and having a first doping profile;
a first common contact layer positioned over the first lower varactor layer, wherein the first lower contact layer, the first lower varactor layer, and the first common contact layer form a first lower varactor;
a first upper varactor layer positioned over the first common contact layer and having a second doping profile that is inverted with respect to the first doping profile;
a first upper contact layer positioned over the first upper varactor layer, wherein the first common contact layer, the first upper varactor layer, and the first upper contact layer form a first upper varactor; and
a first intra-connect structure electrically coupling the first lower contact layer and the first upper contact layer such that the first lower varactor and the first upper varactor are placed in parallel and form a first multi-varactor module;
a second multi-varactor module comprising:
a second lower contact layer positioned over the substrate;
a second lower varactor layer positioned over the second lower contact layer and having the first doping profile;
a second common contact layer positioned over the second lower varactor layer, wherein the second lower contact layer, the second lower varactor layer, and the second common contact layer form a second lower varactor;
a second upper varactor layer positioned over the second common contact layer and having the second doping;
a second upper contact layer positioned over the second upper varactor layer, wherein the second common contact layer, the second upper varactor layer, and the second upper contact layer form a second upper varactor; and
a second intra-connect structure electrically coupling the second lower contact layer and the second upper contact layer such that the second lower varactor and the second upper varactor are placed in parallel and form a second multi-varactor module; and
an inter-connect structure electrically coupling the first and second multi-varactor modules.
